(19) United States
(12) Patent Application Publication
(10) Pub. No.: US 2024/0215437 A1
(43) Pub. Date: Jun. 27, 2024

(54) INORGANIC METAL OXIDE AND MANUFACTURING METHOD THEREOF, AND LIGHT EMITTING DEVICE INCLUDING INORGANIC METAL OXIDE

(71) Applicant: Samsung Display Co., LTD., Yongin-si (KR)

(72) Inventors: CHUL SOON PARK, Yongin-si (KR); WON-JUN PARK, Yongin-si (KR); JONGWOO SHIN, Yongin-si (KR); Yun Ku JUNG, Yongin-si (KR)

(21) Appl. No.: 18/501,365

(22) Filed: Nov. 3, 2023

(30) Foreign Application Priority Data
Dec. 16, 2022 (KR) 10-2022-0176997

(51) Int. Cl. H10K 85/30; C07F 3/06

(52) U.S. Cl. CPC H10K 85/381; C07F 3/06; H10K 50/16

(57) ABSTRACT

According to an embodiment, the inorganic metal oxide includes a crystalline core and a ligand positioned on a surface of the crystalline core, the crystalline core includes crystalline ZnO, and the ligand is a compound represented by Formula 1 below. In Chemical Formula 1, n may indicate 1 or 3, and X may indicate one selected from SH, an amine, methoxysilane, a carboxylic acid, and a carbonyl acid.

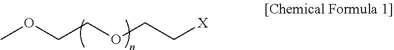

### CROSS-REFERENCE TO RELATED APPLICATION

This application claims priority to and the benefit of Korean Patent Application No. 10-2022-0176997, filed in the Korean Intellectual Property Office on Dec. 16, 2022, the entire contents of which are hereby incorporated by reference.

### BACKGROUND

### 1. Field

Embodiments of the present disclosure relate to an inorganic metal oxide, a method for preparing the same, and a light emitting device including the inorganic metal oxide.

### 2. Description of the Related Art

A light emitting device is a self-emitting device and has a wide viewing angle and excellent contrast, a fast response time, excellent luminance, driving voltage, and response speed characteristics, and multi-colorization.

Quantum dots are used as an emission layer of a light emitting device. The quantum dots (QDs) are semiconductor nanoparticles. Quantum dots having a diameter of nanometers emit light as electrons in an unstable state (e.g., an excited state) descend from a conduction band to a valence band, and when particles of quantum dots become smaller, light having shorter wavelengths is generated, and when the particles are larger, light having longer wavelengths is generated. This is a special, or even unique, electrical and optical characteristic different from those of existing semiconductor materials. Accordingly, visible light having a suitable or desired wavelength may be expressed by adjusting a size of quantum dots, and different sizes of quantum dots and different quantum dot components may be used to realize various suitable colors at the same or substantially the same time.

The above information disclosed in this Background section is only for enhancement of understanding of the background of the disclosure, and therefore, it may contain information that does not form the prior art that is already known in this country to a person of ordinary skill in the art.

### SUMMARY

Embodiments of the present disclosure have been made in an effort to provide an inorganic metal oxide having improved stability over time, a method for preparing the same, and a light emitting device having improved emission efficiency including the inorganic metal oxide.

An embodiment of the present disclosure provides an inorganic metal oxide including a crystalline core and a ligand positioned on a surface of the crystalline core, wherein the crystalline core includes crystalline ZnO, and the ligand is a compound represented by Formula 1 below (e.g., the ligand positioned on the surface of the crystalline core is a reaction product of the compound represented by Formula 1 below and the crystalline core).

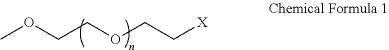

In Chemical Formula 1, n may be 1 or 3, and X may be one selected from SH, an amine, methoxysilane, a carboxylic acid, and a carbonyl acid.

The crystalline core may have a diameter of 10 nm to 200 μm.

In Chemical Formula 1, n may be 1, and X may be SH.

A difference between an initial size of the inorganic metal oxide and the size after 2 weeks may be within 20 times (e.g., may be within a factor of 20).

An embodiment of the present disclosure provides a method of preparing an inorganic metal oxide, the method including: synthesizing crystalline ZnO at a temperature of 50° ° C. to 100° C., and substituting (e.g., reacting) a ligand, which is a compound represented by Chemical Formula 1 below, on a surface of the crystalline ZnO at a temperature of 50° C. to 100° C.

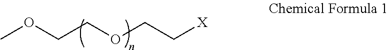

In Chemical Formula 1, n may indicate 1 or 3, and X may indicate one selected from SH, an amine, methoxysilane, a carboxylic acid, and a carbonyl acid.

The crystalline core may have a diameter of 10 nm to 200 μm.

In Chemical Formula 1, n may be 1, and X may be SH.

A difference between an initial size of the inorganic metal oxide and the size after 2 weeks may be within 20 times (e.g., may be within a factor of 20).

An embodiment of the present disclosure provides a light emitting device including: a first electrode; an electron transport layer on the first electrode; an emission layer on the electron transport layer; a hole transport layer on the emission layer; and a second electrode on the hole transport layer; and wherein the electron transport layer includes an inorganic metal oxide, the inorganic metal oxide includes a crystalline core and a ligand positioned on a surface of the crystalline core, the crystalline core includes crystalline ZnO, and the ligand is a compound represented by Chemical Formula 1 (e.g., the ligand positioned on the surface of the crystalline core is derived from the compound represented by Formula 1, for example, is a reaction product of the compound represented by Formula 1 below and the crystalline core). For example, the inorganic metal oxide may include a reaction product of a crystalline core including crystalline ZnO and the compound represented by Chemical Formula 1.

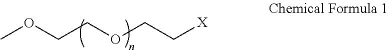

In Chemical Formula 1, n may indicate 1 or 3, and X may indicate one selected from SH, an amine, methoxysilane, a carboxylic acid, and a carbonyl acid.

The first electrode may be a reflecting electrode, and the second electrode may be a transflective electrode.

The crystalline core may have a diameter of 10 nm to 200 μm.

In Chemical Formula 1, n may be 1, and X may be SH.

A thickness of the electron transport layer may be in a range of 200 Å to 400 Å.

The light emitting device may further include an electron injection layer between the electron transport layer and the first electrode.

A thickness of the electron injection layer may be in a range of 1500 Å to 2400 Å.

The electron injection layer may include one or more materials selected from ZnO, TiO₂, WO₃, and SnO₂.

The electron injection layer may include one or more materials selected from ZnO, TiO₂, WO₃, and SnO₂ doped with one selected from Mg, Y, Li, Ga, and Al.

An embodiment of the present disclosure provides a light emitting device including: a first electrode that is a reflective electrode; a hole transport layer on the first electrode; an emission layer on the hole transport layer: an electron transport layer on the emission layer; and a second electrode positioned on the electron transport layer that is a transflective electrode, wherein the electron transport layer includes an inorganic metal oxide, the inorganic metal oxide includes a crystalline core and a ligand positioned on a surface of the crystalline core, the crystalline core includes crystalline ZnO, and the ligand is an inorganic metal oxide compound represented by Chemical Formula 1 (e.g., the ligand positioned on the surface of the crystalline core is a reaction product of the compound represented by Formula 1 below and the crystalline core).

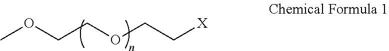

In Chemical Formula 1, n may indicate 1 or 3, and X may indicate one selected from SH, an amine, methoxysilane, a carboxylic acid, and a carbonyl acid.

The crystalline core may have a diameter of 10 nm to 200 μm.

In Chemical Formula 1, n may be 1, and X may be SH.

According to the embodiments, it is possible to provide an inorganic metal oxide having improved stability over time, a method for preparing the same, and a light emitting device having improved emission efficiency including the inorganic metal oxide.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 illustrates an inorganic metal oxide according to an embodiment.

FIG. 2 illustrates a quantum dot including a crystalline ZnO core and a ligand according to an embodiment.

FIG. 3 illustrates a cross-section of a light emitting device according to an embodiment.

FIG. 4 illustrates a cross-section of a light emitting device according to another embodiment.

FIG. 5 illustrates a cross-section corresponding to that of FIG. 3 for a display device according to an embodiment.

FIG. 6 illustrates a cross-section corresponding to that of FIG. 4 for another embodiment.

### DETAILED DESCRIPTION

The subject matter of the present disclosure will be described more fully hereinafter with reference to the accompanying drawings, in which embodiments of the disclosure are shown. As those skilled in the art would realize, the described embodiments may be modified in various suitable different ways, all without departing from the spirit or scope of the present disclosure.

To clearly describe the subject matter of the present disclosure, parts that are irrelevant to the description may not be described, and like numerals refer to like or similar constituent elements throughout the specification.

Further, because sizes and thicknesses of constituent members shown in the accompanying drawings may be arbitrarily given for better understanding and ease of description, the present disclosure is not limited to the illustrated sizes and thicknesses. In the drawings, the thicknesses of layers, films, panels, regions, etc., may be exaggerated for clarity. For example, in the drawings, for better understanding and ease of description, the thicknesses of some layers and areas may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the present specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the present specification, the phrase “in a plan view” means when an object portion is viewed from above, and the phrase “in a cross-sectional view” means when a cross-section taken by vertically cutting an object portion is viewed from the side.

Hereinafter, an inorganic metal, a preparing method thereof, and a display device including the inorganic metal oxide according to an embodiment will be described in more detail with reference to the accompanying drawings.

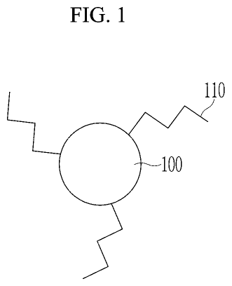

FIG. 1 illustrates an inorganic metal oxide according to an embodiment. Referring to FIG. 1, the inorganic metal oxide according to the present embodiment includes a crystalline core 100 and a ligand 110 positioned on a surface of the crystalline core.

The crystalline core 100 may include crystalline ZnO. In this case, ZnO may be in a crystalline state rather than an amorphous state.

The ligand 110 may include a compound 1 represented by Chemical Formula 1 below (e.g., the ligand 110 may be a reaction product of a reaction of the crystalline core 100 and the compound represented by Chemical Formula 1 below, for example, the ligand 110 may be derived from the compound represented by Chemical Formula 1 below).

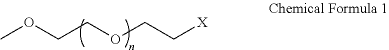

In Chemical Formula 1, n may indicate 1 or 3, and X may indicate one selected from SH, an amine, methoxysilane, a carboxylic acid, and a carbonyl acid. The core 100 may have a diameter of 10 nm to 200 μm.

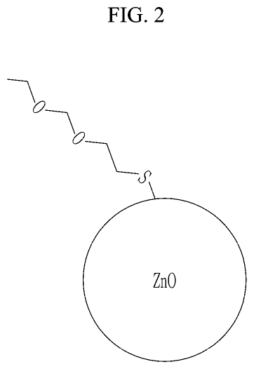

FIG. 2 illustrates an inorganic metal oxide including a crystalline ZnO core and a ligand according to an embodiment. Referring to FIG. 2, the inorganic metal oxide according to the present embodiment includes the crystalline ZnO core and the ligand positioned on a surface of the core. The ligand may be a compound in which n is 1 and X is SH in Chemical Formula 1, but this is merely an example, and the present disclosure is not limited thereto. In some embodiments, as can be seen in FIG. 2, when the ligand is on the surface of the core, X of Chemical Formula 1 may have reacted with the surface of the core to bond the ligand to the surface of the core. For example, when X is SH, reaction of the ligand with the surface of the core may replace the H of SH with a chemical bond (e.g., a covalent bond) from the ligand to the surface of the core.

The inorganic metal oxide according to the present embodiment includes the crystalline ZnO core and the ligand positioned on the surface of the core. As such, as crystalline ZnO particles have excellent stability over time at room temperature (25° C.) and in the air. As a result, they are more suitable for an inkjet process compared with amorphous ZnO particles.

In order to generate the crystalline ZnO particles in this way, synthesis of ZnO particles is required to be performed at a high temperature of 50° C. or higher. In addition, ligand substitution is also required to be performed at a high temperature of 50° C. or higher.

Hereinafter, a method of forming an inorganic metal oxide according to the present embodiment will be described.

First, crystalline ZnO is synthesized. In this case, the synthesis of crystalline ZnO is performed at a high temperature of 50° C. or higher. For example, it may be performed at a temperature of 50° C. to 100° C. When ZnO is synthesized at this temperature, it is crystalline rather than amorphous.

In addition, ligand substitution of crystalline ZnO is also performed at a high temperature. Because crystalline ZnO is more crystallized than amorphous ZnO, a higher reaction temperature is required or desired than when replacing a ligand with amorphous ZnO (e.g., when bonding a ligand to amorphous ZnO). For example, ligand substitution of crystalline ZnO may be achieved at a temperature of 50° C. or higher.

Table 1 below shows dispersion in ink according to a ligand substitution temperature for crystalline ZnO.

TABLE 1

| | |
|---|---|
| Reaction temperature | Dispersion |

| | | |
|---|---|---|
| 25° | C. | X |
| 50° | C. | ◯ |
| 80° | C. | ◯ |
| 100° | C. | ◯ |

Referring to Table 1, in the case of Example 1 in which the ligand substitution was performed at 25° C., it was seen that the dispersion in the ink was poor. This indicates that ligand substitution was not sufficiently performed in crystalline ZnO (e.g., the crystalline ZnO was not sufficiently substituted or functionalized with the ligand). As such, crystalline ZnO having a low dispersion in ink is difficult to proceed with an inkjet process and is not easy to use in an actual display device. In Table 1, it can be seen that, when a ligand substitution reaction temperature is 50° C. or higher, it has dispersibility in the ink, and accordingly, it can be seen that ligand substitution occurs in crystalline ZnO (e.g., the crystalline ZnO is suitably substituted or functionalized with the ligand) when the reaction temperature is higher than 50° C. In addition, while varying the synthesis temperature of the inorganic metal oxide (ZnO), an initial average particle size and an average particle size after 2 weeks were measured and shown in Table 2.

TABLE 2

| | | | | | | Average |
|---|---|---|---|---|---|---|
| | | | | | Initial average | particle size |
| Composition | Inorganic | Synthesis | | | particle size | after 2 weeks |
| name | metal oxide | temperature | | Ligand | (um) | (um) |
| Composition 1 | ZnO | 25° | C. | Compound 1 | 12.0 | 1200 |
| Composition 2 | ZnO | 50° | C. | Compound 1 | 12.5 | 152 |
| Composition 3 | ZnO | 80° | C. | Compound 1 | 13.5 | 50 |
| Composition 4 | ZnO | 100° | C. | Compound 1 | 15.0 | 52 |

Referring to Table 2, it can be seen that a composition 1 in which ZnO is synthesized at 25° C. has an initial particle size of 12 μm, but has an average particle size of 1200 μm after 2 weeks, which is a 100-fold increase in average particle size. When the average particle size increases over time, it is undesirable because, when applied as an inkjet composition, discharge decreases and head clogging occurs after a lapse of time. However, in the case of a composition 2 in which ZnO is synthesized at 50° C., the average particle size is 152 μm after 2 weeks, which is about 10 times higher than the initial average particle size. That is, it can be seen that when synthesizing ZnO at a high temperature, it has crystalline characteristics, and this crystalline ZnO has excellent stability over time.

In addition, a composition 3 where ZnO is synthesized at 80° C. and a composition 4 is synthesized at 100° C. show an average particle size of about 50 μm after 2 weeks, which increased by only about 3 times compared to the initial average particle size, thereby confirming excellent stability over time.

For the compositions 1 to 4, initial discharge property and discharge property after 7 days are measured, and results thereof are shown in Table 3. A Dimatix Materials Printer DMP-2850 was used for inkjet equipment, and discharge performance standard was based on impact accuracy of +20 μm.

TABLE 3

| Composition | Inorganic | Synthesis | | | Initial | Discharge |
|---|---|---|---|---|---|---|
| name | metal oxide | temperature | | Ligand | discharge | after 7 days |
| Composition 1 | ZnO | 25° | C. | Compound 1 | ◯ | X |
| Composition 2 | ZnO | 50° | C. | Compound 1 | ◯ | ◯ |
| Composition 3 | ZnO | 80° | C. | Compound 1 | ◯ | ◯ |
| Composition 4 | ZnO | 100° | C. | Compound 1 | ◯ | ◯ |

As can be seen in Table 3, in the case of the composition 1 where the synthesis temperature of ZnO is 25° ° C., it can be seen that the discharge performance is poor after 7 days. However, in the case of compositions 2 to 4, where the synthesis temperature of ZnO is 50° C. or higher, it can be seen that they have stable discharge properties even after 7 days.

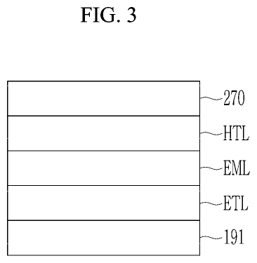

Hereinafter, the light emitting device including the inorganic metal oxide according to the present embodiment will be described. FIG. 3 schematically illustrates a light emitting device according to an embodiment. Referring to FIG. 3, the light emitting device according to the present embodiment may include a first electrode 191, an electron transport layer (ETL), a light emitting layer (ETL), a hole transport layer (HTL), and a second electrode 270.

The first electrode 191 and the second electrode 270 may each include a conductive oxide (e.g., an electrically conductive oxide) such as an indium tin oxide (ITO), an indium zinc oxide (IZO), a zinc tin oxide (ZTO), a copper indium oxide (CIO), a copper zinc oxide (CZO), a gallium zinc oxide (GZO), an aluminum zinc oxide (AZO), a tin oxide (SnO₂), a zinc oxide (ZnO), or a combination thereof, and/or a conductive material (e.g., an electrically conductive material and/or an electrically conductive polymer) such as calcium (Ca), ytterbium (Yb), aluminum (AI), silver (Ag), magnesium (Mg), samarium (Sm), titanium (Ti), gold (Au) and/or an alloy thereof, graphene, carbon nanotubes, and/or PEDOT:PSS. However, the first electrode 191 and the second electrode 270 are not limited thereto, and may be formed in a stacked structure of two or more layers.

In an embodiment, the first electrode 191 may be a reflective electrode having a structure of ITO/Ag/ITO, and the second electrode 270 may be a transflective electrode including AgMg. Light generated from an emission layer EML may be reflected by the first electrode 191, which is a reflective electrode, and may be resonated between the second electrode 270, which is a transflective electrode, and the first electrode 191 to be amplified. The resonated light may be reflected from the first electrode 191 to be emitted to an upper surface of the second electrode 270.

In an embodiment, the second electrode 270 may include an alloy made of two or more materials selected from Ag, Mg, Al, and Yb. For example, the second electrode 270 may include AgMg, and in this case, a content (e.g., an amount) of Ag in the second electrode 270 may be greater than a content (e.g., an amount) of Mg. In this case, the content of Mg may be about 10 volume %. A thickness of the second electrode layer 270 may be in a range of 80 Å to 120 Å. In addition, the second electrode 270 may include AgYb, and in this case, a content of Yb may be about 10 volume %. However, this is merely an example, and the present disclosure is not limited thereto.

The hole transport layer HTL may include at least one selected from m-MTDATA, TDATA, 2-TNATA, NPB(NPD), B-NPB, TPD, Spiro-TPD, Spiro-NPB, Methylated-NPB, TAPC, HMTPD, TCTA(4,4′,4″-tris(N-carbazolyl)triphenylamine), Pani/DBSA (Polyaniline/Dodecylbenzenesulfonic acid), PEDOT/PSS (Poly(3,4-ethylenedioxythiophene)/Poly(4-styrenesulfonate))), Pani/CSA (Polyaniline/Camphor sulfonic acid), and PANI/PSS (Polyaniline/Poly(4-styrenesulfonate)). In some embodiments, the hole transport layer may include an alkali metal halide and/or an alkaline earth metal halide.

The emission layer EML may include an organic material and/or an inorganic material. The emission layer may include quantum dots. For example, the quantum dots may include at least one selected from Zn, Te, Se, Cd, In, and P. The quantum dots may include a core containing at least one selected from Zn, Te, Se, Cd, In, and P, and a shell positioned at a portion of the core and having a different composition from that of the core.

In some embodiments, the quantum dots may be selected from a group II-VI compound, a group I-III-VI compound, a group III-V compound, a group IV-VI compound, a group IV element, and a group IV compound and a combination thereof.

The quantum dots may be selected from a Group II-VI compound which is selected from a two-element compound selected from CdSe, CdTe, CdS, ZnS, ZnSe, ZnTe, ZnO, HgS, HgSe, HgTe, MgSe, MgS, and a mixture thereof; a three-element compound selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a four-element compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The quantum dot may be selected from a three-element compound selected from AgInS, CuInS, AgGaS, and CuGaS, which are a Group I-III-VI compound, and a mixture thereof or four-element compounds such as AgInGaS and CuInGaS.

The Group III-V compound may be selected from a two-element compound selected from GaN, GaP, GaAs, GaSb, AlN, AIP, AIAs, AISb, InN, InP, InAs, InSb, and a mixture thereof; a three-element compound selected from GaNP, GaNAs, GaNSb, GaPAs, GaPSb, AlNP, AlNAs, AlNSb, AlPAS, AlPSb, InGaP, InAlP, InNP, InNAs, InNSb, InPAs, InPSb, and a mixture thereof; and a four-element compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal (e.g., InZnP), and may be selected from these compounds.

The Group IV-VI compound may be selected from a two-element compound selected from SnS, SnSe, SnTe, PbS, PbSe, PbTe, and a mixture thereof; a three-element compound selected from SnSeS, SnSeTe, SnSTe, PbSeS, PbSeTe, PbSTe, SnPbS, SnPbSe, SnPbTe, and a mixture thereof; and a four-element compound selected from SnPbSSe, SnPbSeTe, SnPbSTe, and a mixture thereof. The Group IV element may be selected from Si, Ge and a mixture thereof, and the Group IV compound may be a two-element compound selected from SiC, SiGe, and a mixture thereof.

The electron transport layer (ETL) may include the inorganic metal oxide according to the present embodiment. For example, the electron transport layer ETL may include an inorganic metal oxide including a crystalline core and a ligand positioned on a surface of the crystalline core. The crystalline core 100 may be crystalline ZnO, and the ligand may include the compound 1 represented by Chemical Formula 1 below.

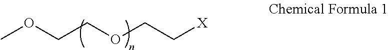

In Chemical Formula 1, n may be 1 or 3, and X may be one selected from SH, amine, methoxysilane, a carboxylic acid, and a carbonyl acid.

A diameter of the inorganic metal oxide may be 10 μm to 200 μm. As described above, the inorganic metal oxide according to the present embodiment may include crystalline ZnO synthesized at a temperature of 50° C. or higher, and ligand exchange can be performed on a surface of the crystalline ZnO at a temperature of 50° C. or higher. Accordingly, stability of the inorganic metal oxide and an ink including the inorganic metal oxide over time is excellent, and inkjet ejection performance is excellent even after a lapse of time.

In the present embodiment, a thickness of the electron transport layer ETL may be 200 Å to 400 Å.

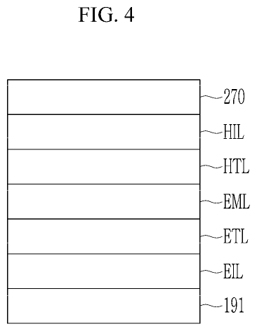

In addition, an electron injection layer positioned between the electron transport layer ETL and the first electrode 191 may be further included. FIG. 4 illustrates a cross-section of a light emitting device according to another embodiment. Referring to FIG. 3, the light emitting device according to the present embodiment is the same as that of FIG. 3 except for further including an electron injection layer EIL positioned between the electron transport layer ETL and the first electrode 191 and a hole injection layer HIL positioned between the hole transport layer HTL and the second electrode 270. A duplicative description of the same constituent elements will not be repeated here. A thickness of the electron injection layer EIL may be 1500 Å to 2400 Å. Referring to FIG. 4, the electron injection layer EIL may include an inorganic metal oxide, e.g., ZnO. In FIG. 4, the inorganic metal oxide included in the electron injection layer EIL may be an inorganic metal oxide according to an embodiment. For example, an inorganic metal oxide in which a ligand of the compound 1 represented by Chemical Formula 1 is substituted in the crystalline ZnO core may be included. In this case, the crystalline ZnO core may be synthesized at a temperature of 50° C. or higher, and the ligand may be substituted on a surface of the crystalline ZnO at a temperature of 50° C. or higher.

In some embodiments, the electron injection layer may include one or more materials selected from ZnO, TiO₂, WO₃, and SnO₂ doped with one selected from Mg, Y, Li, Ga, and Al.

In FIG. 3 and FIG. 4, the first electrode 191 may be connected to a transistor of a display panel to receive a pixel voltage, and the second electrode 270 may receive a common voltage. For example, the light emitting device according to the present embodiment may have a structure in which the electron transport layer ETL is positioned at a side of the first electrode 191, which is a reflective electrode, and the hole transport layer ETL is positioned at a side of the second electrode 270, which is a transflective electrode. This structure has a feature or advantage in that a hole transport layer formation material is free to be selected from a variety of suitable materials because the hole transport layer is formed after the emission layer is formed.

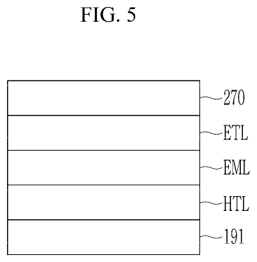

However, this is an example, and a structure in which the hole transport layer HTL is positioned at a side of the first electrode 191 and the electron transport layer ETL is positioned at a side of the second electrode 270 is also possible. FIG. 5 illustrates a cross-section corresponding to that of FIG. 3 for a display device according to an embodiment. Referring to FIG. 5, the light emitting device according to the present embodiment is the same as that of the embodiment of FIG. 3 except that the electron transport layer ETL is positioned between the emission layer EML and the second electrode 270, and the hole transport layer HTL is positioned between the emission layer EML and the first electrode 191. A duplicative description of the same constituent elements will not be repeated here.

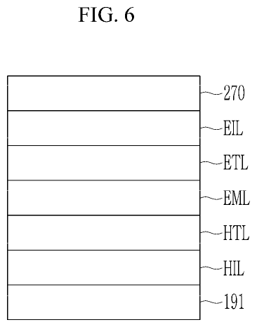

FIG. 6 illustrates a cross-section corresponding to that of FIG. 4 for another embodiment. Referring to FIG. 6, the light emitting device according to the present embodiment is the same as that of the embodiment of FIG. 4 except that the electron transport layer ETL is positioned between the emission layer EML and the second electrode 270, the electron injection layer EIL is positioned between the electron transport layer ETL and the second electrode 270, the hole transport layer HTL is positioned between the emission layer EML and the first electrode 191, and the hole injection layer HIL is positioned between the hole transport layer HTL and the first electrode 191. A duplicative description of the same constituent elements will not be repeated here.

With respect to the light emitting device according to the embodiment of FIG. 3, a driving voltage and efficiency were measured while varying an electron transport layer material, and these results are shown in Table 4.

TABLE 4

| | Composition | Synthesis | Driving voltage | Efficiency |
|---|---|---|---|---|
| Example | name | temperature | (V) | (Cd/A) |
| Example 1 | Composition 1 | 25° C. | 14.2 | 26.7 |
| Example 2 | Composition 2 | 50° C. | 6.3 | 38.3 |
| Example 3 | Composition 3 | 80° C. | 6.2 | 37.2 |

In the Table 4, it can be seen that the driving voltage of Examples 2 and 3 containing ZnO synthesized at 50° C. or higher is lower compared to the light emitting device containing ZnO synthesized at 25° C. (Example 1). In addition, in the case of Examples 2 and 3, it can be seen that the efficiency is increased compared to Example 1. As such, the inorganic metal oxide according to the present embodiment includes a ZnO core synthesized at 50° C. or higher and a ligand substituted at 50° C. or higher. In this case, the ligand may be the compound 1 represented by Chemical Formula 1. Such ZnO has crystalline characteristics, particles do not (or substantially do not) grow over time, stability over time is excellent, and accordingly inkjet discharge performance is excellent, so it is suitable for processing. In addition, it can be seen that the light emitting device including crystalline ZnO has an effect of reducing a driving voltage and increasing luminous efficiency compared to the light emitting device including amorphous ZnO.

While the subject matter of this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims, and equivalents thereof.

What is claimed is:

1. An inorganic metal oxide comprising:
a crystalline core and a ligand positioned on a surface of the crystalline core,
wherein the crystalline core comprises crystalline ZnO, and
the ligand comprises a compound represented by Chemical Formula 1: 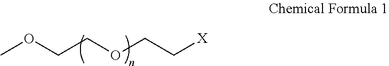
in Chemical Formula 1, n indicates 1 or 3, and X indicates one selected from SH, an amine, methoxysilane, a carboxylic acid, and a carbonyl acid.

2. The inorganic metal oxide of claim 1, wherein:
the crystalline core has a diameter of 10 nm to 200 μm.

3. The inorganic metal oxide of claim 1, wherein:
in Chemical Formula 1, n is 1, and X is SH.

4. The inorganic metal oxide of claim 1, wherein:
a difference between an initial particle size of the inorganic metal oxide and a particle size of the inorganic metal oxide after 2 weeks is within a factor of 20 times.

5. A method of preparing an inorganic metal oxide, the method comprising:
synthesizing crystalline ZnO at a temperature of 50° C. to 100° C.; and
substituting a ligand represented by Chemical Formula 1 on a surface of the crystalline ZnO at a temperature of 50° C. to 100° C.: 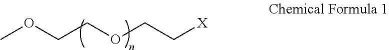
in Chemical Formula 1, n indicates 1 or 3, and X indicates one selected from SH, an amine, methoxysilane, a carboxylic acid, and a carbonyl acid.

6. The method of claim 5, wherein:
the crystalline core has a diameter of 10 nm to 200 μm.

7. The method of claim 5, wherein:
in Chemical Formula 1, n is 1, and X is SH.

8. The preparing method of claim 5, wherein:
a difference between an initial particle size of the inorganic metal oxide and a particle size of the inorganic metal oxide after 2 weeks is within 20 times.

9. A light emitting device comprising:
a first electrode;
an electron transport layer on the first electrode;
an emission layer on the electron transport layer;
a hole transport layer on the emission layer; and
a second electrode on the hole transport layer,
wherein the electron transport layer comprises an inorganic metal oxide,
the inorganic metal oxide comprises:
a crystalline core and a ligand positioned on a surface of the crystalline core,
the crystalline core comprises crystalline ZnO, and
the ligand comprises a compound represented by Chemical Formula 1: 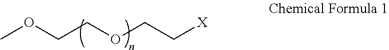
in Chemical Formula 1, n indicates 1 or 3, and X indicates one selected from SH, an amine, methoxysilane, a carboxylic acid, and a carbonyl acid.

10. The light emitting device of claim 9, wherein:
the first electrode is a reflective electrode, and
the second electrode is a transflective electrode.

11. The light emitting device of claim 9, wherein:
the crystalline core has a diameter of 10 nm to 200 μm.

12. The light emitting device of claim 9, wherein:
in Chemical Formula 1, n is 1, and X is SH.

13. The light emitting device of claim 9, wherein:
a thickness of the electron transport layer is in a range of 200 Å to 400 Å.

14. The light emitting device of claim 9, further comprising:
an electron injection layer between the electron transport layer and the first electrode.

15. The light emitting device of claim 14, wherein:
a thickness of the electron injection layer is in a range of 1500 Å to 2400 Å.

16. The light emitting device of claim 14, wherein:
the electron injection layer comprises one or more materials selected from ZnO, TiO₂, WO₃, and SnO₂.

17. The light emitting device of claim 14, wherein:
the electron injection layer comprises one or more materials selected from ZnO, TiO₂, WO₃, and SnO₂ doped with one selected from Mg, Y, Li, Ga, and Al.

18. A light emitting device comprising:
a first electrode that is a reflective electrode;
a hole transport layer on the first electrode;
an emission layer on the hole transport layer;
an electron transport layer on the emission layer; and
a second electrode positioned on the electron transport layer that is a transflective electrode,
wherein the electron transport layer comprises an inorganic metal oxide,
the inorganic metal oxide comprises:
a crystalline core and a ligand positioned on a surface of the crystalline core,
the crystalline core comprises crystalline ZnO, and
the ligand comprises a compound represented by Chemical Formula 1: 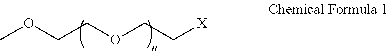
in Chemical Formula 1, n indicates 1 or 3, and X indicates one selected from SH, an amine, methoxysilane, a carboxylic acid, and a carbonyl acid.

19. The light emitting device of claim 18, wherein:
the crystalline core has a diameter of 10 nm to 200 μm.

20. The light emitting device of claim 18, wherein:
in Chemical Formula 1, n is 1, and X is SH.
